(19) United States
(12) Patent Application Publication
(10) Pub. No.: US 2025/0070778 A1
(43) Pub. Date: Feb. 27, 2025

(54) DETECTION CIRCUIT, DETECTION METHOD, AND MOBILE TERMINAL

(71) Applicant: Realme Mobile Telecommunications (Shenzhen) Co., Ltd, Shenzhen (CN)

(72) Inventor: Jiangyan YANG, Shenzhen (CN)

(73) Assignee: Realme Mobile Telecommunications (Shenzhen) Co., Ltd, Shenzhen (CN)

(21) Appl. No.: 18/944,298

(22) Filed: Nov. 12, 2024

Related U.S. Application Data
(63) Continuation of application No. PCT/CN2022/144043, filed on Dec. 30, 2022.

(30) Foreign Application Priority Data
May 13, 2022 (CN) 202210533385.2

(51) Int. Cl. H03K 17/955; H01Q 1/24; H01Q 5/307

(52) U.S. Cl. CPC H03K 17/955; H01Q 1/243; H01Q 5/307

(57) ABSTRACT

A detection circuit includes a first antenna module and a capacitive proximity sensor, the first antenna module includes a multiplexer, a first antenna and a first inductor. One terminal of the multiplexer is connected to the first antenna, and the multiplexer is configured for controlling the first antenna to operate in different operating frequency bands. The other terminal of the multiplexer is connected to a ground terminal. The first inductor is connected in parallel with the multi-path switch. The capacitive proximity sensor is connected to the first antenna and configured for detecting a capacitance value of the first antenna module. A detection method and a mobile terminal are further provided.

### CROSS-REFERENCE TO RELATED APPLICATIONS

The present application is a continuation of International Patent Application No. PCT/CN2022/144043, filed Dec. 30, 2022, which claims priority to Chinese Patent Application No. 202210533385.2, filed May 13, 2022, both of which are herein incorporated by reference in their entireties.

### TECHNICAL FIELD

The present disclosure relates to the field of control technologies, and in particular to a detection circuit, a detection method, a detection device, a mobile terminal, and a non-transitory computer-readable storage medium.

### BACKGROUND

In related art, a capacitive proximity sensor configured on a mobile terminal is configured to determine whether there is an object approaching based on changes in capacitance. However, during the use of the mobile terminal, an internal circuit may also cause capacitance changes, so that the capacitive proximity sensor incorrectly determines that the object is approaching, reducing the detection accuracy of the capacitive proximity sensor.

### SUMMARY OF THE DISCLOSURE

The technical solutions in the embodiments of the present disclosure are implemented as follows.

The embodiments of the present disclosure provide a detection circuit including a first antenna module and a capacitive proximity sensor.

The first antenna module includes a first antenna, a multiplexer, and a first inductor. One terminal of the multiplexer is connected to the first antenna and configured to control the first antenna to operate in different operating frequency bands, and the other terminal of the multiplexer is connected to a ground terminal. The first inductor is connected in parallel with the multiplexer.

The capacitive proximity sensor is connected to the first antenna and configured for detecting a capacitance value of the first antenna module.

In some embodiments, in a plurality of antennas configured on a mobile terminal, the first antenna is the antenna that meets a set condition; and the set condition includes at least one of the following conditions: the maximum number of supported operating frequency bands; and the maximum range of supported transmission frequencies.

In some embodiments, an inductance value of the first inductor is greater than or equal to 82 nanohenries and less than or equal to 100 nanohenries.

In some embodiments, the capacitive proximity sensor is connected to a feeding point of the first antenna, so that in the case where an object approaches the first antenna module, an induced capacitance is formed between the first antenna and the object.

In some embodiments, the multiplexer is connected in parallel with the first inductor, so that the first inductor is configured to filter out capacitance generated during switching of the multiplexer.

The embodiments of the present disclosure further provide a detection method, and the detection method includes the following operations:
determining a first detection result of the capacitive proximity sensor of the detection circuit, wherein the detection circuit is the detection circuit of any one of above embodiments; and
determining a second detection result based on the first detection result, wherein the second detection result indicates whether there is an object whose distance from the first antenna module of the detection circuit is less than or equal to a first set threshold.

In some embodiments, the detection method further includes: determining transmission power of the first antenna based on the second detection result.

In some embodiments, the determining transmission power of the first antenna based on the second detection result, includes:
adjusting the transmission power of the first antenna from a first power level to a second power level in the case where the second detection result indicates that a distance between the first antenna module and an object to be detected is less than or equal to the first set threshold; wherein the transmission power corresponding to the first power level is greater than the transmission power corresponding to the second power level.

In some embodiments, the determining a second detection result based on the first detection result, includes:
determining that the second detection result indicates there is the object whose distance from the first antenna module of the detection circuit is less than or equal to the first set threshold in the case where the first detection result indicates that a capacitance value of the first antenna module is within a first set range; and
determining that the second detection result indicates there is no the object whose distance from the first antenna module of the detection circuit is less than or equal to the first set threshold in the case where the first detection result indicates that the capacitance value of the first antenna module is not within the first set range.

The embodiments of the present disclosure further provide a mobile terminal including a processor and a memory. The memory is configured for storing a computer program that is able to run on the processor.

The processor is configured to implement operations of the detection method of any one of above embodiments in response to running the computer program.

### BRIEF DESCRIPTION OF THE DRAWINGS

FIG. 1 is a schematic view illustrating a connection of a detection circuit in the related art.

FIG. 2 is a schematic view illustrating a detection principle of a capacitive sensor.

FIG. 3 is a schematic view illustrating a connection of a detection circuit in some embodiments of the present disclosure.

FIG. 4 is a schematic flow chart of the detection method in some embodiments of the present disclosure.

FIG. 5 is a structural schematic view of a detection device in some embodiments of the present disclosure.

FIG. 6 is a structural schematic view illustrating a hardware composition of a mobile terminal in some embodiments of the present disclosure.

### DETAILED DESCRIPTION

In the following description, specific details such as specific system structures, technologies, etc., are provided for illustration rather than limitation, so as to facilitate a thorough understanding of the embodiments of the present disclosure. However, those of ordinary skill in the art should know that, the present disclosure may also be implemented in other embodiments without the specific details. In other cases, details of a well-known system, apparatus, and method may be omitted to avoid hindering the description of the present disclosure by unnecessary details.

It should be noted that technical solutions in the embodiments of the present disclosure may be in any combination when there is no conflict.

In addition, in the embodiments of the present disclosure, the terms “first”, “second”, etc. are configured to distinguish similar objects and not necessarily configured to describe a specific order or sequence.

Before describing the technical solutions of the embodiments of the present disclosure in detail, a brief description of a detection circuit in related art may be given first.

In view of this, the embodiments of the present disclosure provide an output detection circuit, a detection method, a detection device, a mobile terminal, and a non-transitory computer-readable storage medium. It may at least solve the problem that the detection accuracy of the capacitive proximity sensor reduces, because the capacitive proximity sensor in related art incorrectly determines there is an object approaching.

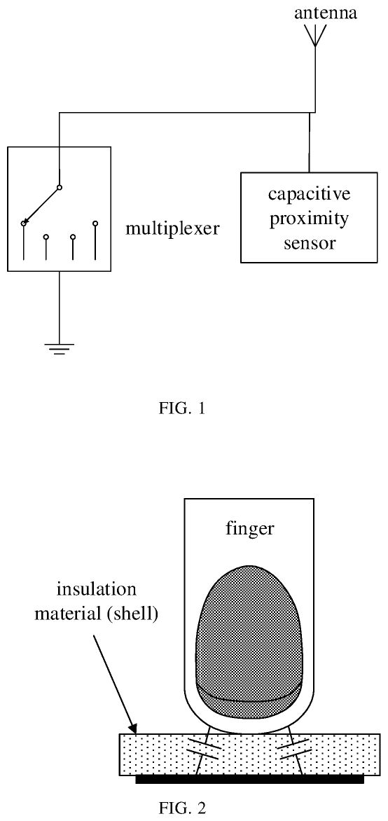

FIG. 1 is a schematic view illustrating a connection of a detection circuit in the related art. As illustrated in FIG. 1, the detection circuit in FIG. 1 includes a multiplexer, an antenna, and a capacitive proximity sensor. One terminal of the multiplexer is connected to the antenna, the other terminal of the multiplexer is connected to a ground terminal. The capacitive proximity sensor is connected to the antenna. When the detection circuit operational, the capacitive proximity sensor may detect a capacitance value of a connection path where the antenna is located or connected. It determines whether an object approaches an area where the antenna is located based on the capacitance value. As illustrated in FIG. 2. FIG. 2 is a schematic view illustrating a detection principle of a capacitive sensor. In the case of a human body approaching the area where the antenna is located (including touching the area where the antenna is located), the human body is equivalent to a capacitor connected to the ground terminal, so that an induced capacitance is formed between the antenna and the ground terminal.

In the detection circuit illustrated in FIG. 1, there are two situations that may trigger changes in the capacitance value of the connection path where the antenna is located. A first situation is that the capacitance is generated due to changes in the external environment. In the first situation, the capacitance is generated because the object approaches the area where the antenna is located. A second situation is that the capacitance is generated by an internal circuit of the antenna. The multiplexer of the detection circuit may control an operating frequency band of a first antenna. For example, a four-way switch provides a RF1 operating frequency band, a RF2 operating frequency band, a RF3 operating frequency band, and a RF4 operating frequency band, respectively. In response to the four-way switch switching between RF1, RF2, RF3, and RF4, the connection path where the antenna is located may generate different sizes of capacitance.

In practical applications, the capacitive proximity sensor cannot distinguish the different situations generating the capacitance. Therefore, in the case where the capacitance is generated by the internal circuit of the antenna, the capacitive proximity sensor may incorrectly determine that the object approaches the area where the antenna is located based on the detected capacitance value, resulting in misjudgment, thereby reducing the detection accuracy of the capacitive proximity sensor.

Based on this, in each embodiment of the present disclosure, the capacitance generated by the internal circuit of the antenna may be prevented from being detected by the capacitive proximity sensor, thereby improving the detection accuracy of the capacitive proximity sensor.

The present disclosure may be explained in detail by combining the accompanying drawings and embodiments.

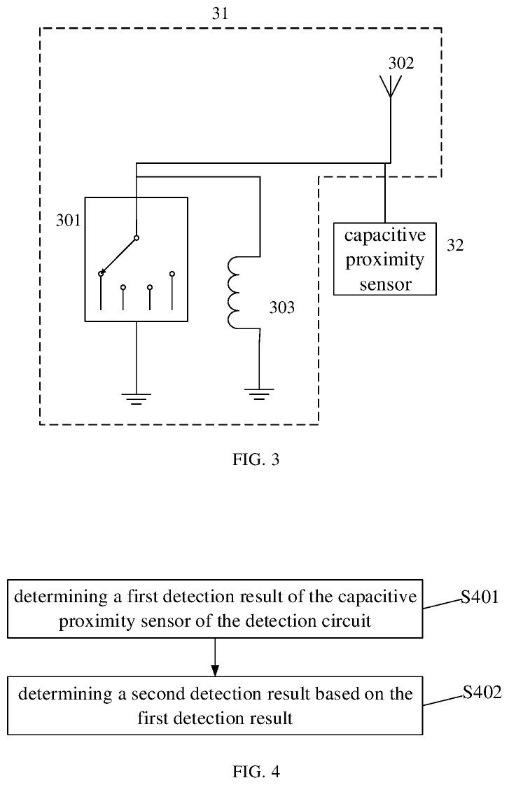

In some embodiments of the present disclosure, a detection circuit is provided. FIG. 3 is a schematic view illustrating a connection of a detection circuit in some embodiments of the present disclosure. As illustrated in FIG. 3, the detection circuit includes a first antenna module 31 and a capacitive proximity sensor 32. The first antenna module 31 includes a multiplexer 301, a first antenna 302, and a first inductor 303.

In the first antenna module 31, one terminal of the multiplexer 301 is connected to the first antenna 302, and the other terminal of the multiplexer 301 is connected to the ground terminal. In some embodiments, the multiplexer 301 may be different types of switches, such as a single pole double throw switch (SP2T), a single pole four throw switch (SP4T), a double pole double throw switch (2P2T), a double pole four throw switch (2P4T), etc. The multiplexer 301 may control the first antenna 302 to operate in different operating frequency bands. In some embodiments, the multiplexer 301 is the SP4T and may provide four different operating frequency bands for the first antenna 302, so as to expand bandwidth; and the multiplexer 301 is also enable the first antenna 302 to operate in the operating frequency band that meets the bandwidth requirements.

The first inductor 303 is connected in parallel with the multiplexer 301. The first inductor 303 has a direct current passing function. In response to the multiplexer 301 continuously switching to change the operating frequency band of the first antenna 302, different sizes of capacitance or different sizes of inductance may be generated during the switching of the multiplexer 301. The capacitance or the inductance may flow into the ground terminal through the first inductor 303, so that the capacitance value of the first antenna module 31 cannot undergo significant changes.

In some embodiments, the inductance with an inductance value greater than or equal to 82 nanohenries and less than or equal to 100 nanohenries is selected as the first inductor 303.

The capacitive proximity sensor 32 is connected to the first antenna 302. In some embodiments, the capacitive proximity sensor 32 is connected to a feeding point of the first antenna 302, so that the first antenna 302 may serve as a metal sensing pad for the capacitive proximity sensor 32. In the case where the object approaches the first antenna module 31, an induced capacitance may be formed between the metal sensing pad (i.e., the first antenna 302) and the object. That is, the capacitive proximity sensor 32 uses the first antenna 302 as a detection path. In response to the object approaching or moving away from the first antenna module 31 (including all directions in the area where the first antenna 302 is located), the capacitive proximity sensor 32 may detect the capacitance value of the first antenna module 31. Due to the direct current passing function of the first inductor 303 (that is the direct current may pass through the first inductor 303), the capacitance generated by the multiplexer 301 may be eliminated. Therefore, the capacitance detected by the capacitive proximity sensor 32 is generated by the external environment (i.e. the object approaching), which improves the detection accuracy of the capacitive proximity sensor 32.

In the above embodiments, the first inductor 303 is connected in parallel with the multiplexer 301, the capacitance generated during the switching of the multiplexer 301 may be eliminated or filtered out through the first inductor 303. Therefore, it may ensure that the capacitance change detected by the capacitive proximity sensor 32 is caused by the object approaching or moving away from the first antenna 302, thereby improving the detection accuracy of the capacitive proximity sensor 32.

In some embodiments, in the case where the mobile terminal is configured with multiple antennas, the first antenna 302 is the antenna that meets a set condition in the mobile terminal, so that the capacitive proximity sensor 32 may reuse the first antenna 302 as the metal sensing pad. In the practical applications, the selection of the first antenna 302 is related to the specific design of the capacitive proximity sensor 32. However, generally, the antenna with the maximum number of supported operating frequency bands, and/or the antenna with the maximum range of supported transmission frequencies, may be used as the first antenna 302. The operating frequency band refers to a transmission frequency band. In the practical applications, the antenna with the maximum range of supported transmission frequencies is used as the first antenna 302, so that the transmission power of the first antenna 302 significantly reduces in response to reducing a radiation value of the mobile terminal.

In the above embodiments, the detection circuit includes the first antenna module 31 and the capacitive proximity sensor 32. The first antenna module 31 includes the multiplexer 301, the first antenna 302, and the first inductor 303. One terminal of the multiplexer 301 is connected to the first antenna 302 and configured for controlling the first antenna 302 to operate in different operating frequency bands. The other terminal of the multiplexer 301 is connected to the ground terminal. The first inductor 303 is connected in parallel with the multiplexer 301. The capacitive proximity sensor 32 is connected to the first antenna 302 and configured for detecting the capacitance value of the first antenna module 31. Therefore, the capacitance generated during switching the multiplexer 301 may filtered out through the first inductor 303, avoiding the false triggering of the capacitive proximity sensor 32 caused by the capacitance generated by the internal circuit of the first antenna module 31, thereby improving the detection accuracy of the capacitive proximity sensor 32.

In some embodiments of the present disclosure, a detection method is further provided. As illustrated in FIG. 4, the detection method includes the following operations.

In an operation S401, the detection method may include determining a first detection result of the capacitive proximity sensor 32 of the detection circuit.

In the embodiments of the present disclosure, the detection circuit is the detection circuit as illustrated in FIG. 3. The capacitive proximity sensor 32 is able to detect the capacitance value of the first antenna module 31. Because the multiplexer 301 is connected in parallel with the first inductor 303, the first inductor 303 may filter out the capacitance generated during the switching of the multiplexer 301. Therefore, the capacitive proximity sensor 32 may not detect the capacitance generated by the multiplexer 301. The capacitive proximity sensor 32 may detect the capacitance value of the first antenna module 31 that is generated in response to the object approaching the first antenna module 31. The first detection result may be determined by the capacitive proximity sensor 32, and the first detection result may reflect the capacitance value of the first antenna module 31.

In an operation S402, the detection method may include determining a second detection result based on the first detection result.

The capacitive proximity sensor 32 may detect the capacitance value of the first antenna module 31 that is generated in response to the object approaching the first antenna module 31. Based on the first detection result, the second detection result may be determined. The second detection result may reflect whether there is the object (including the human body) approaching the first antenna module 31. The object that a distance between the object and the first antenna module 31 is less than or equal to a first set threshold is defined as the object approaching the first antenna module 31. That is, the object is defined as approaching the first antenna module 31 in response to the distance between the object and the first antenna module 31 is less than or equal to the first set threshold. In the practical applications, the detection circuit is usually configured on the mobile terminal, and the capacitive proximity sensor 32 may also be configured to determine whether the human body approaches the first antenna module 31. In the practical applications, the first set threshold is the maximum distance that the object may cause the first antenna module 31 to generate the induced capacitance. In response to the distance between the object and the first antenna module 31 being greater than the maximum distance, it may be considered that the object moves away from the first antenna module 31, and in this case, the object cannot cause the first antenna module 31 to generate the induced capacitance.

In the above embodiments, the first detection result of the capacitive proximity sensor 32 of the detection circuit is determined, and the second detection result is determined based on the first detection result. The first detection result of the capacitive proximity sensor 32 may accurately reflect the capacitance that is generated in response to the object approaching the first antenna module 31, thereby improving the detection accuracy of the capacitive proximity sensor 32.

In some embodiments, the correspondence between the first detection result and the second detection result is described. In the practical applications, in the case where the object approaches or even touches the first antenna module 31, the object acts as the capacitor connected to the ground terminal. The first antenna module 31 acts as the metal sensing pad of the capacitive proximity sensor 32, the induced capacitance may be formed between the first antenna module 31 and the ground terminal. The capacitance of the induced capacitance is within a first set range (usually several pF to tens of pF). By determining whether the first detection result matches the first set range, the corresponding second detection result may be obtained.

The first detection result indicates that the capacitance value of the first antenna module 31 is within the first set range, and the capacitive proximity sensor 32 detects the capacitance generated by the object approaching the first antenna module 31. It may be determined that the second detection result indicates there is the object whose distance from the first antenna module 31 is less than or equal to the first set threshold.

The first detection result indicates that the capacitance value of the first antenna module 31 is not within the first set range. This is, the capacitive proximity sensor 31 detects that the capacitance value of the first antenna module 31 is less than the minimum capacitance value within the first set range, or the capacitive proximity sensor 31 detects that the capacitance value of the first antenna module 31 is greater than the maximum capacitance value within the first set range. It may be considered that the capacitive proximity sensor 31 detects that there is no capacitance in the first antenna module 31, or the capacitance value detected by the capacitive proximity sensor 31 is not generated by the object approaching the first antenna module 31. It may be determined that the second detection result indicates there is no object whose distance from the first antenna module 31 is less than or equal to the first set threshold.

In some embodiments, the mobile terminal is able to generate electromagnetic radiation, and the electromagnetic radiation refers to the phenomenon that energy is emitted into a space in the form of an electromagnetic wave. The electromagnetic radiation greater than 2 milligauss may cause illness in the human body. In the practical applications, a specific absorption rate (SAR) is usually configured to measure the magnitude of the electromagnetic radiation. In order to reduce the impact of the electromagnetic radiation from the mobile terminal, the SAR of the mobile terminal may be adjusted by using the capacitive proximity sensor 32. In some embodiments, the SAR of the mobile terminal is adjusted by adjusting the transmission power of the first antenna 302, and the transmission power of the first antenna 302 is determined based on the second detection result.

In some embodiments, in the case where the second detection result indicates there is the object whose distance from the first antenna module 31 is less than or equal to the first set threshold, it may correspond to a user using the mobile terminal for communication, so that the user approaches the mobile terminal, or a distance between the user and the mobile terminal is too close. In this case, it is necessary to reduce the SAR of the mobile terminal, so as to avoid harm to the user caused by the electromagnetic radiation from the mobile terminal. In some embodiments, the transmission power of the first antenna 302 is adjusted from a first power level to a second power level. That is, the transmission power of the first antenna 302 reduces, thereby reducing the SAR of the mobile terminal.

In the practical applications, the second detection result changes, for example, the change from the presence of the object whose distance from the first antenna module 31 is less than or equal to the first set threshold to the absence of such an object. For example, the user may place the mobile terminal at a location away from themselves after ending a call, thereby transitioning from being close to the mobile terminal to being away from the mobile terminal, and as a result, the corresponding second detection result changes. In this case, the transmission power of the first antenna 302 may be adjusted from the second power level to the first power level, increasing the transmission power of the first antenna 302.

In the above embodiments, the second detection result is detecting whether there is the capacitance in the first antenna module 31 based on the capacitive proximity sensor 32, and the capacitance is generated by the object approaching the first antenna module 31. Therefore, it may accurately identify the situation that the user approaches the mobile terminal, thereby accurately adjusting the transmission power of the first antenna 302 and reducing the SAR of the mobile terminal. Therefore, it may avoid changes in the transmission power of the first antenna 302 due to incorrect triggering of the capacitive proximity sensor 32.

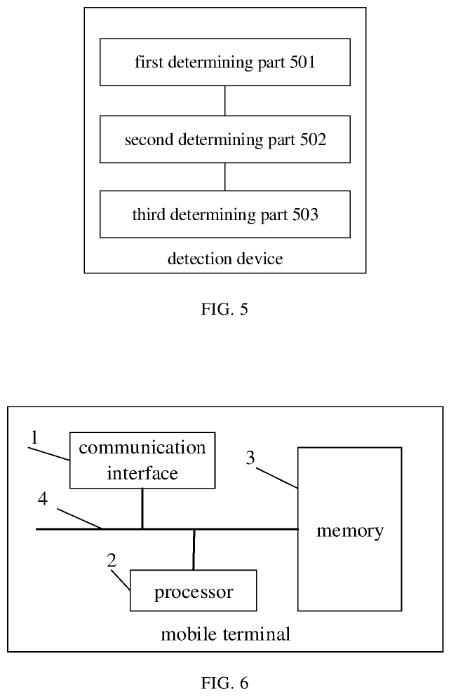

In order to implement the detection method in the embodiments of the present disclosure, in some embodiments, a detection device is further provided. As illustrated in FIG. 5, the detection device includes a first determining part 501, a second determining part 502, and a third determining part 503.

The first determining part 501 is configured to determine the first detection result of the capacitive proximity sensor 32 of the detection circuit. The detection circuit includes any one of the detection circuits described in the above embodiments.

The second determining part 502 is configured to determine the second detection result based on the first detection result. The second detection result indicates whether there is the object whose distance from the first antenna module 31 of the detection circuit is less than or equal to the first set threshold.

In some embodiments, the detection device includes the first determining part 501 and the second determining part 502.

In some embodiments, the detection device further includes the third determining part 503. The third determining part 503 is configured to determine the transmission power of the first antenna 302 based on the second detection result.

In some embodiments, the third determining part 503 is configured not only for determining the transmission power of the first antenna 302 based on the second detection result, but also for:

adjusting the transmission power of the first antenna 302 from the first power level to the second power level in the case where the second detection result indicates that the distance between the first antenna module 31 and the object is less than or equal to the first set threshold, wherein the transmission power corresponding to the first power level is greater than the transmission power corresponding to the second power level.

In some embodiments, the second determining part 502 is configured not only for determining the second detection result based on the first detection result, but also for:
determining that the second detection result indicates there is the object whose distance from the first antenna module 31 of the detection circuit is less than or equal to the first set threshold in the case where the first detection result indicates that the capacitance value of the first antenna module 31 is within the first set range; and
determining that the second detection result indicates there is no the object whose distance from the first antenna module 31 of the detection circuit is less than or equal to the first set threshold in the case where the first detection result indicates that the capacitance value of the first antenna module 31 is not within the first set range.

In the practical applications, the first determining part 501, the second determining part 502, and the third determining part 503 may be implemented by a processor of the detection device. The processor needs to run programs stored in a memory, so as to implement the functions of the various program modules mentioned above.

It should be noted that the detection device in the above embodiment of FIG. 5 only illustrates the division of each program module during detection. In the practical applications, the above processing may be assigned to different program modules according to need. That is, the internal structure of the detection device may be divided into different program modules to complete all or part of the processing described above. In addition, the detection device and detection method in the above embodiments belong to the same concept, and the specific implementation process of the detection device is detailed in the method embodiments, which may not be repeated here.

Based on the hardware implementation of the above program modules, and in order to implement the detection method in the embodiments of the present disclosure, the embodiments of the present disclosure further provide an electronic device. FIG. 6 is a structural schematic view illustrating a hardware composition of the electronic device in some embodiments of the present disclosure. As illustrated in FIG. 6, the electronic device includes a communication interface 1 and a processor 2.

The communication interface 1 is able to exchange information with other devices, such as a network device.

The processor 2 is connected to the communication interface 1, so as to exchange information with other devices. The processor 2 is configured to implement one or more detection methods in above embodiments in response to running the computer programs. And the computer program is stored on memory 3.

In the practical applications, the various components of the electronic device are coupled together through a bus system 4. The bus system 4 is configured to achieve connection and communication between these components. The bus system 4 includes not only a data bus, but also a power bus, a control bus, and a status signal bus. However, for the sake of clarity, various buses are labeled as the bus system 4 in FIG. 6.

The memory 3 in the embodiments of the present disclosure is configured to store various types of data to support the operation of the electronic device. The data includes any computer program configured for operating on the electronic device.

The memory 3 may be a volatile memory or a non-volatile memory, or the memory 3 may include the volatile memory and the non-volatile memory. The non-volatile memory may be a Read-Only Memory (ROM), a Programmable Read-Only Memory (PROM), an Erasable Programmable Read-Only Memory (EPROM), an Electrically Erasable Programmable Read-Only Memory (EEPROM), a Ferromagnetic Random Access Memory (FRAM), a Flash Memory, a magnetic surface memory, a compact disk, or a Compact Disc Read-Only Memory (CD-ROM). The magnetic surface memory may be a disk memory or a magnetic tape memory. The volatile memory may be a Random Access Memory (RAM) which serves as an external cache. By way of exemplary but not restrictive illustrations, many forms of RAMs are available, such as a Static Random Access Memory (SRAM), a Synchronous Static Random Access Memory (SSRAM), a Dynamic Random Access Memory (DRAM), a Synchronous Dynamic Random Access Memory (SDRAM), a Double Data Rate Synchronous Dynamic Random Access Memory (DDRSDRAM), an Enhanced Synchronous Dynamic Random Access Memory (ESDRAM), a SyncLink Dynamic Random Access Memory (SLDRAM), and a Direct Rambus Random Access Memory (DRRAM).

The memory 3 described in the embodiments is intended to include, but is not limited to, these and any other suitable types of memories.

The method disclosed in the above embodiments of the present disclosure may be applied to the processor 2 or implemented by the processor 2. The processor 2 may be an integrated circuit chip with a signal processing capability. In the implementation process, each operation of the above method may be completed through an integrated logic circuit of the hardware or instructions in software form in the processor 2. The processor 2 may be a general-purpose processor, a Digital Signal Processor (DSP), or other programmable logic devices, a discrete gate or transistor logic device, or a discrete hardware component, etc. The processor 2 may implement or execute the disclosed methods, operations, and logic diagrams in the embodiments of the present disclosure. The general-purpose processor may be a microprocessor or any conventional processor, etc. The operations of the method disclosed in the embodiments of the present disclosure may be implemented by a hardware decoding processor, or a combination of the hardware module and the software module of the decoding processor. The software module may be disposed in a non-transitory computer-readable storage medium, and the non-transitory computer-readable storage medium is disposed in the memory 3. The processor 2 reads the program in the memory 3. The operations of the method are implemented by the processor 2 combined with the hardware.

The processes corresponding to the various methods in the embodiments of the present disclosure are implemented in response to the processor 2 executing the program. For the sake of simplicity, these processes may not be repeated here.

In some embodiments of the present disclosure, a non-transitory computer-readable storage medium is further provided, such as the memory 3 that stores the computer program. The computer program may be executed by the processor 2, so as to implement the operations in the method of any one of the above embodiments. The computer readable storage media may be the memory, such as the FRAM, the ROM, the PROM, the EPROM, the EEPROM, the Flash Memory, the magnetic surface storage, the Compact Disc, or the CD-ROM storage, etc.

In the embodiments of the present disclosure, the detection circuit includes the first antenna module and the capacitive proximity sensor. The first antenna module includes the multiplexer, the first antenna, and the first inductor. One terminal of the multiplexer is connected to the first antenna and configured for controlling the first antenna to operate in different operating frequency bands. The other terminal of the multiplexer is connected to the ground terminal. The first inductor is connected in parallel with the multiplexer. The capacitive proximity sensor is connected to the first antenna and configured for detecting the capacitance value of the first antenna module. Therefore, the capacitance generated during switching the multiplexer may filtered out through the first inductor, avoiding the false triggering of the capacitive proximity sensor caused by the capacitance generated by the internal circuit of the first antenna module, thereby improving the detection accuracy of the capacitive proximity sensor.

In the several embodiments provided in the present disclosure, it should be understood that the disclosed device, terminal, and method may be implemented in other manners. The described device embodiments are merely exemplary. For example, the unit division is merely a logical function division and may be other divisions during actual implementation. For example, a plurality of units or components may be merged or integrated into another system, or some features may be ignored or not performed. In addition, the coupling, direct coupling, or communication connection between the various components displayed or discussed may be indirect coupling or communication connection through some interfaces, devices, or units, which may be electrical, mechanical, or other forms.

The units described as separation components may be or may not be physically separated. The component used as display unit may be or may not be a physical unit. That is, the units may be located in the same place, or may be distributed to many network units. Some or all of the units may be selected according to actual requirements, so as to implement the solutions of the embodiments.

In addition, functional units in the embodiments of the present disclosure may be all integrated in a processing unit, each unit is separately used as one unit, or two or more units are integrated in one unit. The integrated unit may be implemented in a form of hardware, or may be implemented in form of a combination of a hardware functional unit and a software functional unit.

Those of ordinary skill in the art may understand that all or part of the operations to implement the above method embodiments may be completed through the hardware related to program instructions. The aforementioned program may be stored in a non-transitory computer-readable storage medium. During executing the program, the operations of the above method embodiments are implemented; The aforementioned computer-readable storage media may include various media that may store program code, such as a mobile storage device, the ROM, the RAM, a disk, or the compact disc.

Alternatively, when the integrated units mentioned above are implemented in the form of the software functional module, and sold or used as an independent product, the integrated units may also be stored in the non-transitory computer-readable storage medium. Based on such an understanding, the technical solution of the embodiments of the present disclosure essentially or partially contribute to the related art may be reflected in the form of a software product. The software product is stored in the non-transitory computer-readable storage medium and includes several instructions for enabling an electronic device (which may be a personal computer, a server, or a network device, etc.) to perform all or a part of the methods described in various embodiments of the present disclosure. The aforementioned computer-readable storage media may include various media that may store program code, such as the mobile storage device, the ROM, the RAM, the disk, or the compact disc.

The descriptions are only specific implementations of the present disclosure, but are not intended to limit the protection scope of the present disclosure. Any variation or replacement readily figured out by persons skilled in the art within the technical scope disclosed in the present disclosure should fall within the protection scope of the present disclosure. Therefore, the protection scope of the present disclosure should be subject to the protection scope of the claims.

What is claimed is:

1. A detection circuit, comprising:
a first antenna module, comprising a first antenna, a first inductor, and a multiplexer; wherein one terminal of the multiplexer is connected to the first antenna and configured to control the first antenna to operate in different operating frequency bands, and the other terminal of the multiplexer is connected to a ground terminal; and the first inductor is connected in parallel with the multiplexer; and
a capacitive proximity sensor, connected to the first antenna and configured for detecting a capacitance value of the first antenna module.

2. The detection circuit according to claim 1, wherein in a plurality of antennas configured on a mobile terminal, the first antenna is one of the antennas that meets a set condition; and the set condition comprises at least one of the following conditions:
the maximum number of supported operating frequency bands; and
the maximum range of supported transmission frequencies.

3. The detection circuit according to claim 1, wherein an inductance value of the first inductor is greater than or equal to 82 nanohenries and less than or equal to 100 nanohenries.

4. The detection circuit according to claim 1, wherein the capacitive proximity sensor is connected to a feeding point of the first antenna, so that in the case where an object approaches the first antenna module, an induced capacitance is formed between the first antenna and the object.

5. The detection circuit according to claim 1, wherein the multiplexer is connected in parallel with the first inductor, so that the first inductor is configured to filter out capacitance generated during switching of the multiplexer.

6. A detection method, comprising:
determining a first detection result of a capacitive proximity sensor of a detection circuit, wherein the detection circuit comprises:
a first antenna module, comprising a first antenna, a first inductor, and a multiplexer; wherein one terminal of the multiplexer is connected to the first antenna and configured to control the first antenna to operate in different operating frequency bands, and the other terminal of the multiplexer is connected to a ground terminal; and the first inductor is connected in parallel with the multiplexer; and
the capacitive proximity sensor, connected to the first antenna and configured for detecting a capacitance value of the first antenna module; and
determining a second detection result based on the first detection result, wherein the second detection result indicates whether there is an object whose distance from the first antenna module of the detection circuit is less than or equal to a first set threshold.

7. The detection method according to claim 6, wherein the detection method further comprises:
determining transmission power of the first antenna based on the second detection result.

8. The detection method according to claim 7, wherein the determining transmission power of the first antenna based on the second detection result, comprises:
adjusting the transmission power of the first antenna from a first power level to a second power level in the case where the second detection result indicates that a distance between the first antenna module and an object to be detected is less than or equal to the first set threshold;
wherein the transmission power corresponding to the first power level is greater than the transmission power corresponding to the second power level.

9. The detection method according to claim 6, wherein the determining a second detection result based on the first detection result, comprises:
determining that the second detection result indicates there is the object whose distance from the first antenna module of the detection circuit is less than or equal to the first set threshold in the case where the first detection result indicates that a capacitance value of the first antenna module is within a first set range; and
determining that the second detection result indicates there is no the object whose distance from the first antenna module of the detection circuit is less than or equal to the first set threshold in the case where the first detection result indicates that the capacitance value of the first antenna module is not within the first set range.

10. The detection method according to claim 6, wherein in a plurality of antennas configured on a mobile terminal, the first antenna is one of the antennas that meets a set condition; and the set condition comprises at least one of the following conditions:
the maximum number of supported operating frequency bands; and
the maximum range of supported transmission frequencies.

11. The detection method according to claim 6, wherein an inductance value of the first inductor is greater than or equal to 82 nanohenries and less than or equal to 100 nanohenries.

12. The detection method according to claim 6, wherein the capacitive proximity sensor is connected to a feeding point of the first antenna, so that in the case where the object approaches the first antenna module, an induced capacitance is formed between the first antenna and the object.

13. The detection method according to claim 6, wherein the multiplexer is connected in parallel with the first inductor, so that the first inductor is configured to filter out capacitance generated during switching of the multiplexer.

14. A mobile terminal, comprising:
a processor; and
a memory, configured for storing a computer program that is able to run on the processor,
wherein the processor is configured to implement operations of a detection method in response to running the computer program, and the detection method comprises:
determining a first detection result of a capacitive proximity sensor of a detection circuit, wherein the detection circuit comprises:
a first antenna module, comprising a first antenna, a first inductor, and a multiplexer; wherein one terminal of the multiplexer is connected to the first antenna and configured to control the first antenna to operate in different operating frequency bands, and the other terminal of the multiplexer is connected to a ground terminal; and the first inductor is connected in parallel with the multiplexer; and
the capacitive proximity sensor, connected to the first antenna and configured for detecting a capacitance value of the first antenna module; and
determining a second detection result based on the first detection result, wherein the second detection result indicates whether there is an object whose distance from the first antenna module of the detection circuit is less than or equal to a first set threshold.

15. The mobile terminal according to claim 14, wherein the detection method further comprises:
determining transmission power of the first antenna based on the second detection result.

16. The mobile terminal according to claim 15, wherein the determining transmission power of the first antenna based on the second detection result, comprises:
adjusting the transmission power of the first antenna from a first power level to a second power level in the case where the second detection result indicates that a distance between the first antenna module and an object to be detected is less than or equal to the first set threshold;
wherein the transmission power corresponding to the first power level is greater than the transmission power corresponding to the second power level.

17. The mobile terminal according to claim 14, wherein the determining a second detection result based on the first detection result, comprises:
determining that the second detection result indicates there is the object whose distance from the first antenna module of the detection circuit is less than or equal to the first set threshold in the case where the first detection result indicates that a capacitance value of the first antenna module is within a first set range; and
determining that the second detection result indicates there is no the object whose distance from the first antenna module of the detection circuit is less than or equal to the first set threshold in the case where the first detection result indicates that the capacitance value of the first antenna module is not within the first set range.

18. The mobile terminal according to claim 14, wherein in a plurality of antennas configured on a mobile terminal, the first antenna is one of the antennas that meets a set condition; and the set condition comprises at least one of the following conditions:
the maximum number of supported operating frequency bands; and
the maximum range of supported transmission frequencies.

19. The mobile terminal according to claim 14, wherein an inductance value of the first inductor is greater than or equal to 82 nanohenries and less than or equal to 100 nanohenries.

20. The mobile terminal according to claim 14, wherein the capacitive proximity sensor is connected to a feeding point of the first antenna, so that in the case where the object approaches the first antenna module, an induced capacitance is formed between the first antenna and the object.
